(19) United States
(12) Patent Application Publication
(10) Pub. No.: US 2026/0248055 A1
(43) Pub. Date: Aug. 20, 2026

(54) HEAT SPREADING LAYER MATERIAL AND SYSTEM-ON-A-CHIP INCLUDING THE SAME

(71) Applicant: Chien-Min SUNG, New Taipei (TW)

(72) Inventor: Chien-Min SUNG, New Taipei (TW)

(21) Appl. No.: 19/539,690

(22) Filed: Feb. 13, 2026

(30) Foreign Application Priority Data
Feb. 20, 2025 (TW) 114106260

(51) Int. Cl. H10W 90/00

(52) U.S. Cl. CPC H10W 90/734

(57) ABSTRACT

A heat spreading layer, which is an at least partially transparent silicon carbide wafer or a slice of the silicon carbide wafer. The heat spreading layer serves as an insulating layer of a chip, and the silicon carbide wafer or the slice thereof has a thermal conductivity higher than that of copper.

### FIELD OF THE INVENTION

This invention relates to semiconductor technology, and more particularly to a heat dissipation structure using a silicon carbide wafer as a heat spreading layer material while simultaneously providing electrical insulation, which is applicable to high-density packaging technologies such as system-on-a-chip (SoC).

### BACKGROUND OF THE INVENTION

With the continuous miniaturization of transistors in integrated circuits, mass production of 4-nanometer process nodes has been achieved, and 2-nanometer technologies are actively under development. Driven by the increasing demand for high-performance computing in artificial intelligence (AI), advanced packaging technologies have evolved toward stacking high bandwidth memory (HBM) and integrating processors such as graphics processing units (GPU) into system-on-a-chip (SoC) architectures.

To accommodate such architectures, large metal lids are commonly used, and silicon interposers are employed to redistribute electrical signals to printed circuit boards (PCB), which is known as Chip-on-Wafer-on-Substrate (CoWoS) technology.

However, as transistor density increases to hundreds of billions, localized hotspots become difficult to dissipate, thereby limiting performance scaling. Conventional silicon interposers exhibit relatively low thermal conductivity (approximately 150 W/m·K), which restricts heat removal efficiency and degrades system reliability.

### SUMMARY OF THE INVENTION

In some embodiments, a heat spreading layer is presented. The heat spreading layer comprises an at least partially transparent silicon carbide wafer or a slice thereof, used as an insulating layer of a chip, wherein the silicon carbide wafer or the slice thereof has a thermal conductivity higher than that of copper.

In some embodiments, a heat spreading layer is presented. The heat spreading layer comprises a first wafer and a second wafer. The first wafer is an at least partially transparent silicon carbide wafer or a slice thereof, and is used as an insulating layer. The second wafer is a gallium nitride wafer, a gallium oxide wafer, or a slice thereof. The first wafer and the second wafer are bonded together by wafer bonding.

### BRIEF DESCRIPTION OF THE DRAWINGS

Example embodiments of the present disclosure will be described with reference to the accompanying drawings briefly described below.

FIG. 1 is a side view of one embodiment of the present invention.

FIG. 2 is a schematic diagram of another embodiment of the present invention.

FIG. 3 is a schematic diagram of a further embodiment of the present invention.

FIG. 4 is a schematic diagram of a chip packaging structure according to one embodiment of the present invention.

FIG. 5 is a schematic diagram of another chip packaging structure according to the present invention.

FIG. 6 is a schematic diagram of a chip module according to one embodiment of the present invention.

FIG. 7 is a schematic diagram of another chip module according to the present invention.

### DETAILED DESCRIPTION

The terminology used herein is for the purpose of describing particular embodiments only and is not intended to limit the present invention. Unless otherwise indicated by the context, the singular forms “a” and “the” include plural forms.

Directional terms used herein, such as “upper”, “lower”, “left”, “right”, “front”, “rear”, and derivatives or synonyms thereof, refer to the relative positions of elements in the accompanying drawings and are not intended to limit the present invention, unless otherwise expressly stated by the context.

Integrated circuit chips have now entered an era of vertical or three-dimensional (3D) stacking, and therefore thermal hotspots within chips are more difficult to dissipate, which easily leads to reliability issues. In addition, when stacking chips, an interposer is often required to redistribute chip terminals or solder balls, and since the interposer must be formed with a large number of vias and electroplated to form conductive routing, relatively high mechanical strength is required. At present, silicon is the most commonly used interposer material; however, silicon has relatively low thermal conductivity (approximately 150 W/m·K), making it difficult to effectively remove localized heat. To address this problem, the present invention adopts at least partially transparent silicon carbide (SiC) as an interposer material, such as single-crystal silicon carbide, which has a thermal conductivity approximately three times that of silicon and can significantly increase the operating frequency and heat dissipation performance of stacked chips.

The present invention relates to a heat spreading layer material, which may also function as a thermal interface material, and is mainly used to alleviate interfacial stress between a heat dissipation surface of a high thermal expansion metal (such as copper) and a heat generating surface of a chip formed of a low thermal expansion material.

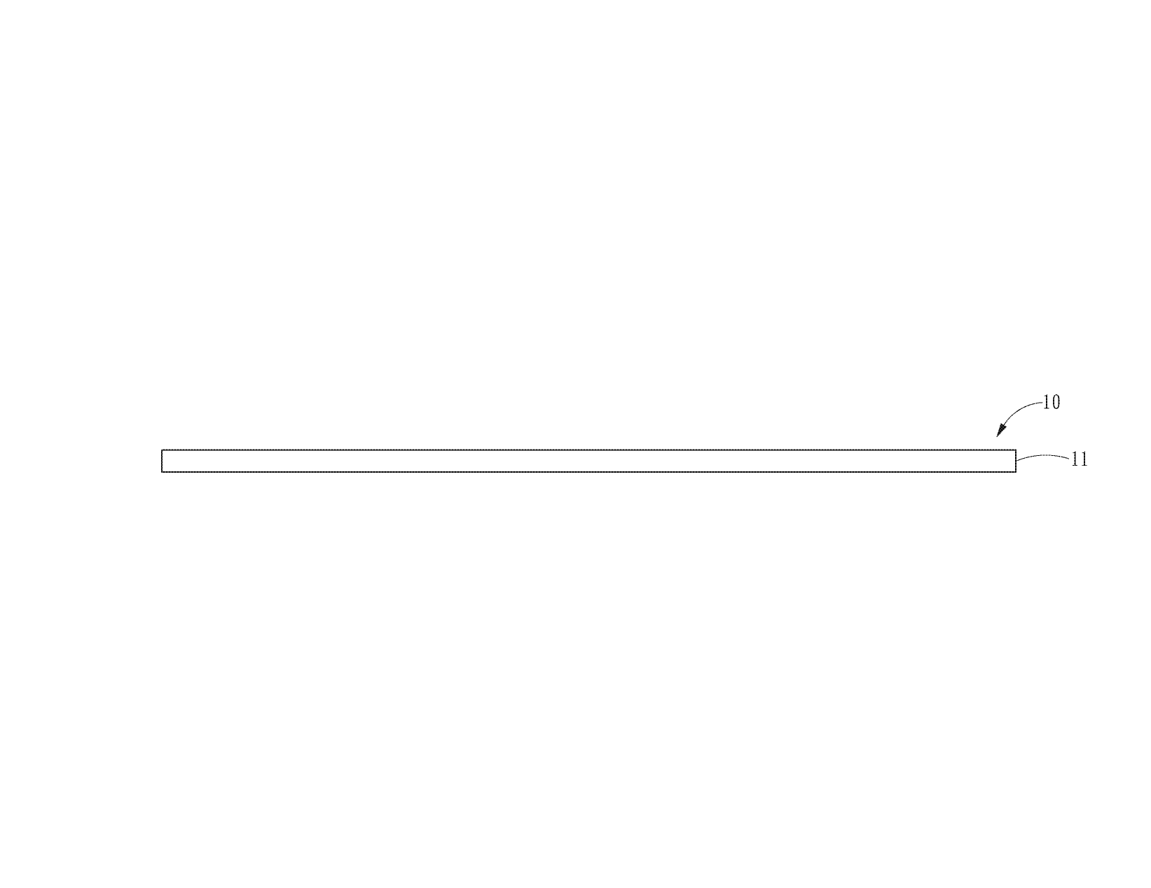

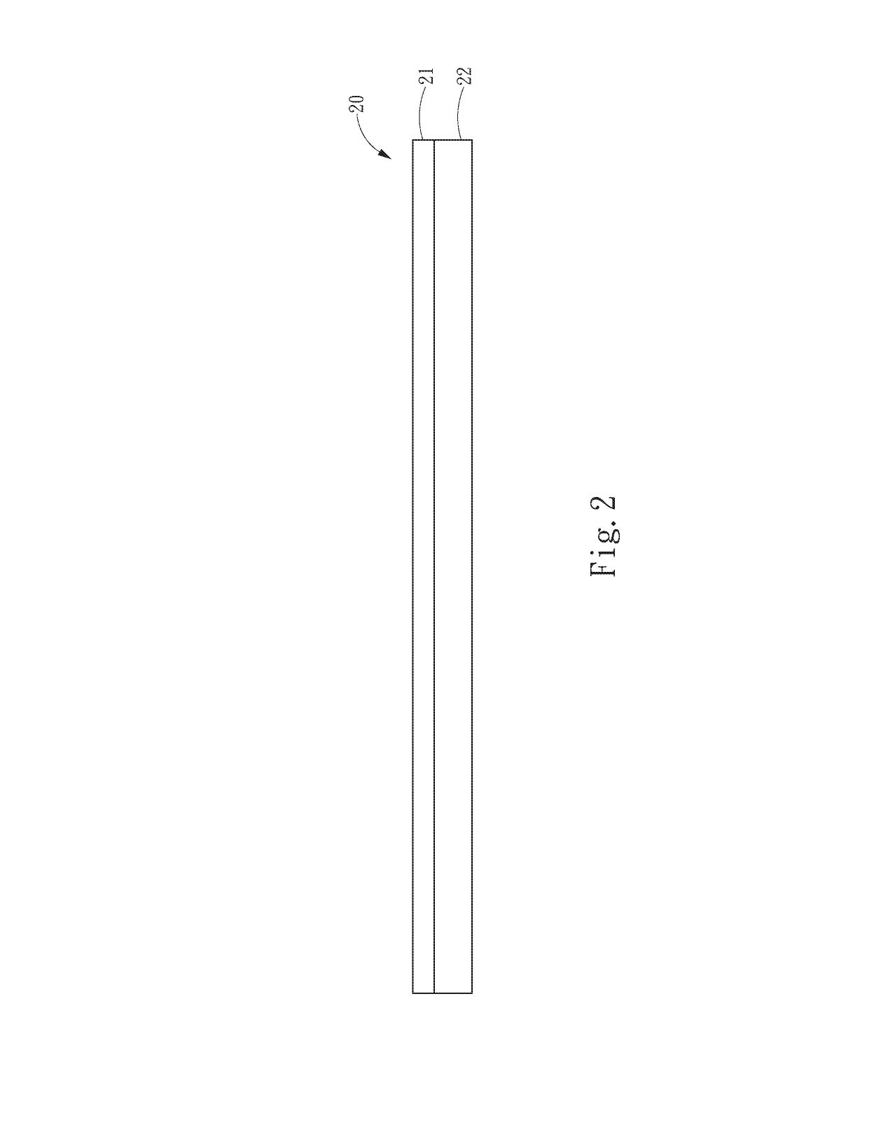

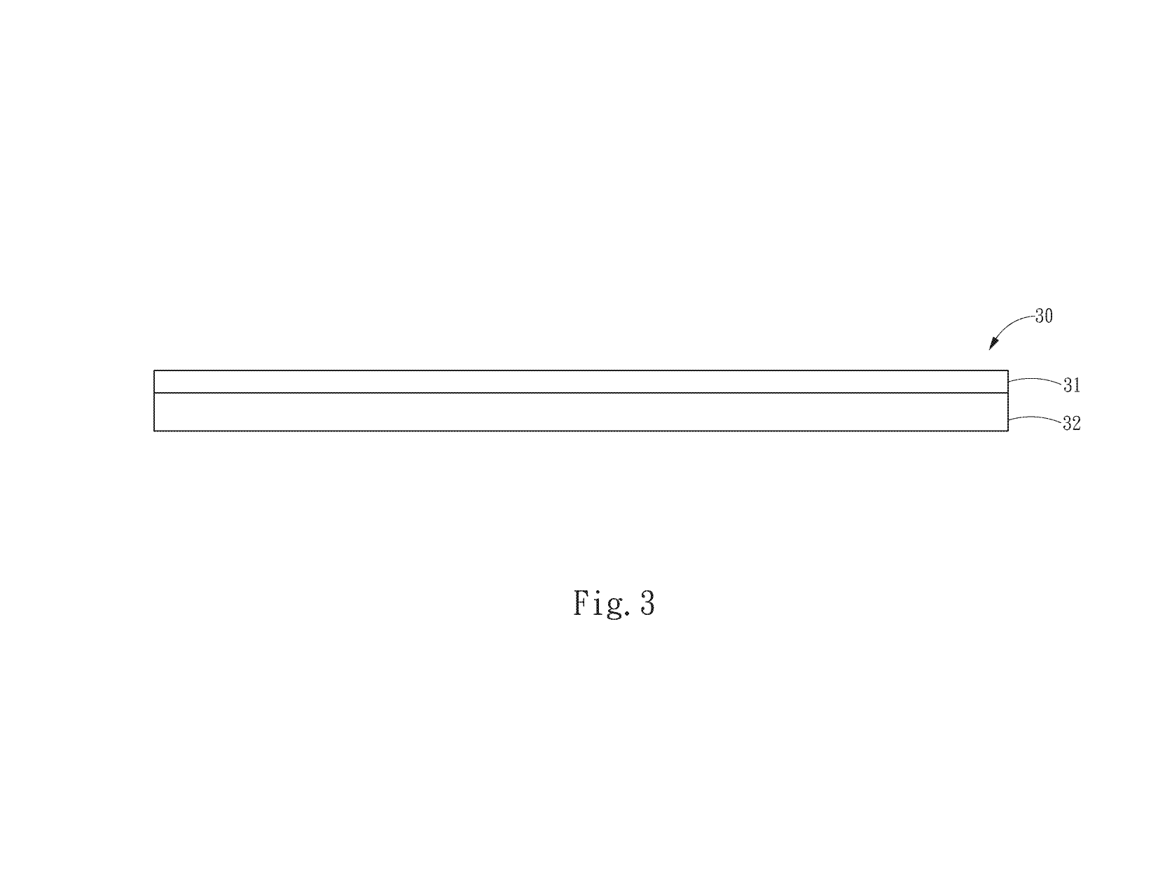

Referring to FIG. 1, according to one aspect of the present invention, the heat spreading layer material 10 is an at least partially transparent silicon carbide wafer 11, and the silicon carbide wafer 11 may serve as an insulating layer of a chip. Referring to FIG. 2, according to another aspect of the present invention, the heat spreading layer material 20 includes a first wafer 21 and a second wafer 22, the first wafer 21 is an at least partially transparent silicon carbide wafer and serves as an insulating layer, the second wafer 22 may be a gallium nitride (GaN) wafer or a gallium oxide (Ga₂O₃) wafer, and the first wafer 21 and the second wafer 22 are bonded to each other, for example by wafer bonding. The first wafer 21 may be disposed on the second wafer 22, and the second wafer 22 may also be disposed on the first wafer 21, without limitation. Referring to FIG. 3, according to a further aspect of the present invention, the heat spreading layer material 30 is an at least partially transparent silicon carbide wafer 31 disposed on a thinned silicon wafer 32, and the silicon carbide wafer 31 is bonded to the thinned silicon wafer 32 by soft solder. According to another aspect of the present invention, the heat spreading layer material 10 may be an at least partially transparent silicon carbide slice of the silicon carbide wafer.

The silicon carbide wafer may refer to a silicon carbide material obtained by slicing from a grown silicon carbide boule or ingot. In an example, the silicon carbide wafer and/or the silicon carbide slice has a thickness of less 1 mm, such as from 50 µm to 800 µm, from 100 µm to 500 µm, or from 200 µm to 400 µm. In some examples, the silicon carbide wafer is single-crystal. In other examples, the silicon carbide wafer is not strictly single-crystal, and may have a microstructure comprising a limited number of crystal grains. In such non-single-crystal examples, the crystal grains may have similar crystallographic orientations or only small orientation differences between adjacent grains, such that the silicon carbide wafer remains at least partially transparent. Accordingly, depending on the specific example, the at least partially transparent silicon carbide wafer may include single-crystal SiC, quasi-single-crystal SiC, large-grain SiC, few-grain SiC wafers, or low-angle grain boundary SiC. In particular, the silicon carbide of the present invention is not formed by sintering processes or by thin-film deposition processes.

In some examples, the at least partially transparent characteristic of the silicon carbide wafer reflects a bulk crystal structure having high lattice integrity and low defect density. Such a crystal structure may be a single-crystal structure, a substantially perfect single-crystal structure, or a bulk crystal structure with only a limited number of crystal imperfections. Due to the reduced presence of crystal defects and grain boundary scattering, these crystal structures are capable of supporting efficient phonon transport and thus provide high thermal conductivity.

The silicon carbide wafer has a thermal conductivity higher than that of copper, for example higher than 400 W/m·K. In some examples, the heat spreading layer materials 10, 30 and the first wafer 21 may also be slices of an at least partially transparent silicon carbide wafer. In other words, the heat spreading layer materials 10, 30 and the first wafer 21 are not necessarily a whole wafer, but may be slices of the wafer, and may have a square shape, a rectangular shape, or other geometric shapes.

In semiconductor devices and advanced packaging structures, if a heat spreading or heat dissipation layer is electrically conductive, leakage current or unintended electrical paths may be introduced, which can adversely affect device performance and reliability. This is particularly critical when the heat spreading layer is disposed in close proximity to active semiconductor regions or is incorporated as part of an interposer or a stacked structure. Accordingly, in some examples, the silicon carbide wafer of the present invention is electrically insulating or exhibits high electrical resistivity, such that leakage current is effectively avoided. As a result, the silicon carbide wafer can be safely incorporated into a chip or a packaging structure as a heat spreading layer or a thermal conduction element, thereby providing efficient heat spreading or heat dissipation without introducing electrical leakage or short-circuit risks.

According to other aspects of the present invention, the present invention further relates to a system-on-a-chip, comprising a thinned silicon wafer and a heat sink formed on the thinned silicon wafer, wherein the heat sink is a transparent silicon carbide wafer.

In one example, the silicon carbide wafers 11 and 31, as well as the first wafer 21, may be single-crystal, and when the heat spreading layer materials 10, 20, and 30 serve as insulating layers, they may function as an interposer of a chip or as a direct bonded copper ceramic substrate.

Examples of preparing the heat spreading layer materials 10, 20, and 30 are described below. In one example, a 12-inch silicon carbide wafer is first used to form an interposer. The interposer is then soldered onto a 12-inch silicon wafer that forms a system-on-a-chip (SoC) by soft solder. In other words, the 12-inch silicon carbide wafer is bonded to the 12-inch silicon wafer. The 12-inch silicon carbide wafer serves as the interposer, and the 12-inch silicon wafer serves as the system-on-a-chip. After bonding, dicing is performed to obtain individual chips. By utilizing the high thermal conductivity and mechanical strength of silicon carbide, the heat dissipation performance and reliability of the packaged system-on-a-chip are improved. In another example, an 8-inch silicon carbide wafer is used as a base substrate. Copper is formed on an upper surface and a lower surface of the silicon carbide wafer. The wafer is then diced into insulating layer suitable for insulated gate bipolar transistors (IGBT). Silicon carbide is used as a substrate material with high mechanical strength and good thermal conductivity, and is combined with copper layers to achieve required electrical connection or heat dissipation functions, thereby improving the heat dissipation and electrical performance of IGBT packaging.

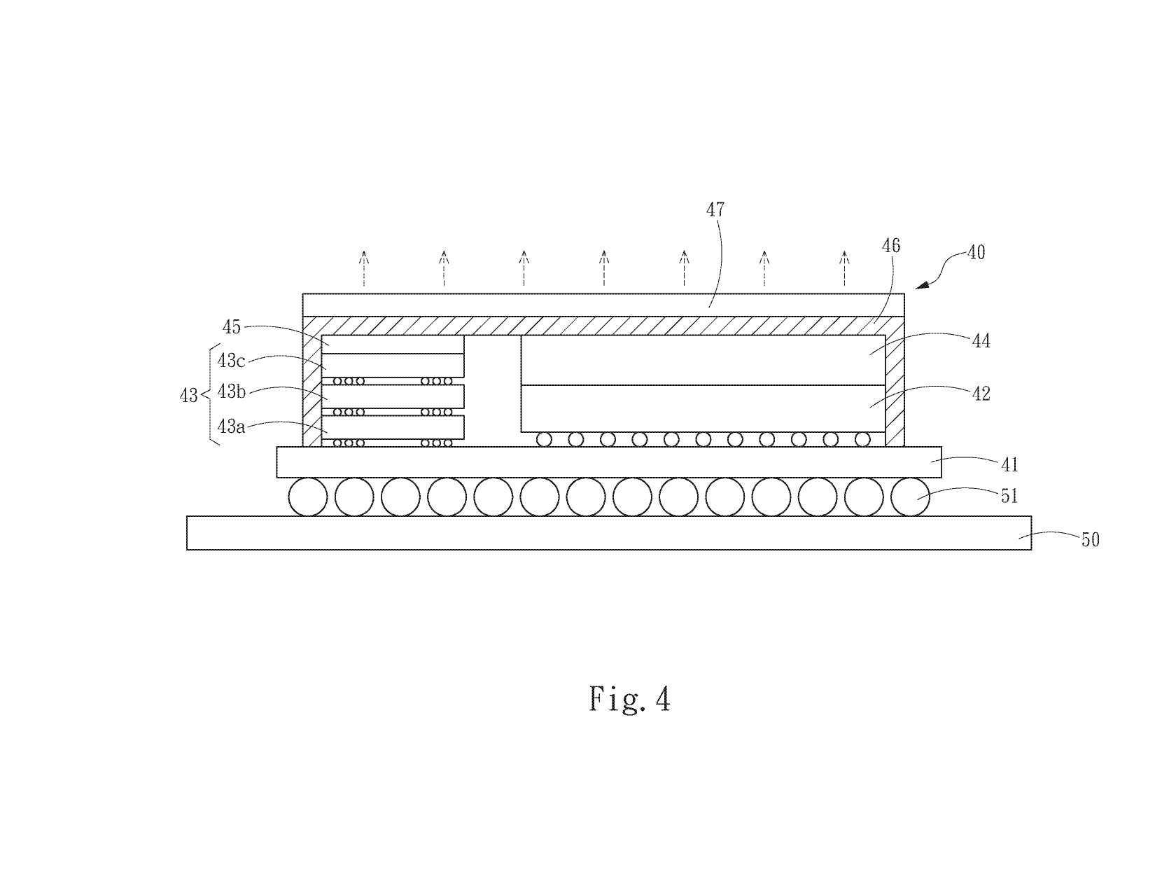

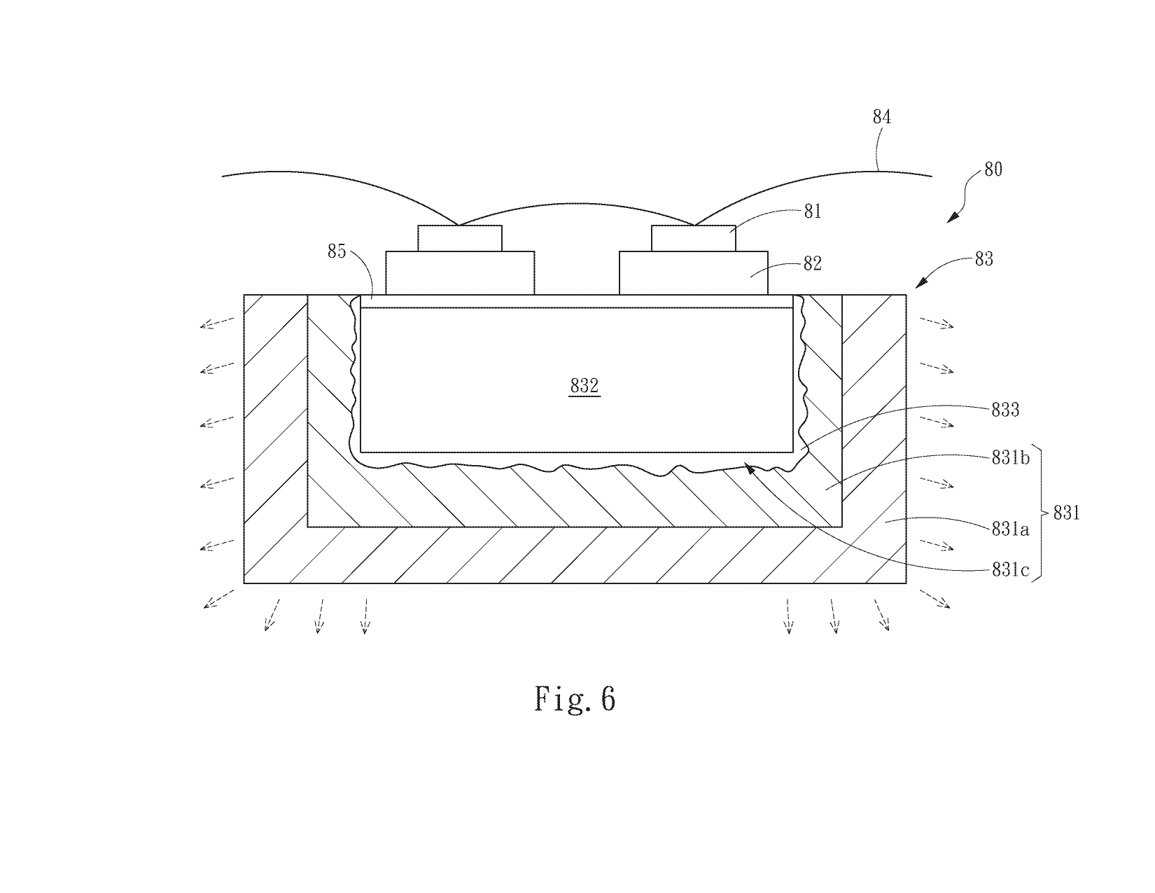

The heat spreading layer material may be used in the examples shown in FIGS. 4 to 7. FIG. 4 illustrates a chip packaging structure 40 according to one embodiment of the present invention. The chip packaging structure 40 is disposed on a printed circuit board 50. The chip packaging structure 40 is connected to the printed circuit board 50 through a solder ball array 51. The chip packaging structure 40 includes an interposer 41, a processor chip 42, a plurality of memory chips 43, a first thermal interface material 44, a second thermal interface material 45, a lid 46, and a third thermal interface material 47. In this example, the processor chip 42 is a graphics processing unit (GPU). The memory chips 43 include a plurality of high bandwidth memories (HBM) 43a, 43b, and 43c. In this example, the interposer 41 may be the silicon carbide wafer described above. The lid 46 may also be the silicon carbide wafer described above.

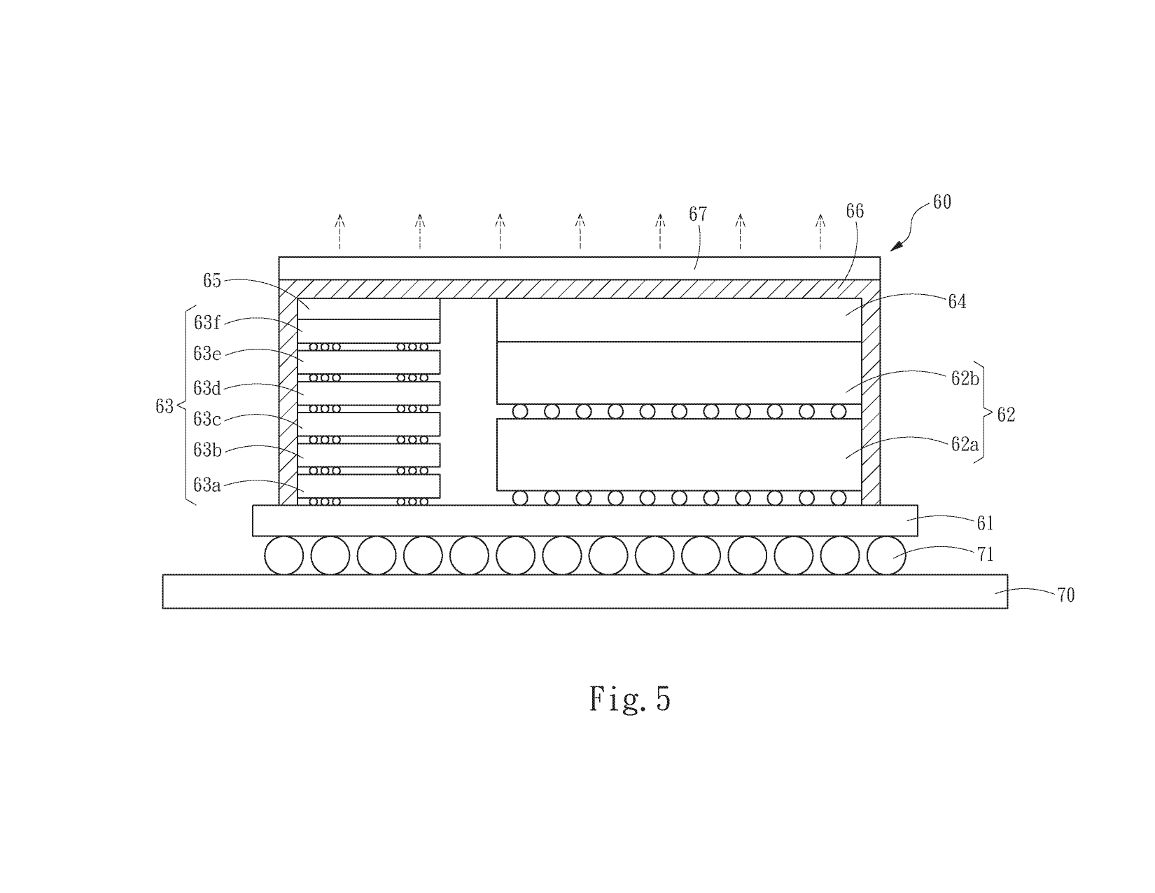

FIG. 5 illustrates another chip packaging structure 60 according to one embodiment of the present invention. The chip packaging structure 60 is disposed on a printed circuit board 70. The chip packaging structure 60 is connected to the printed circuit board 70 through a solder ball array 71. The chip packaging structure 60 includes an interposer 61, a plurality of processor chips 62, a plurality of memory chips 63, a first thermal interface material 64, a second thermal interface material 65, a lid 66, and a third thermal interface material 67. In this example, the processor chips 62 include a plurality of graphics processing units (GPU) 62a and 62b. The memory chips 63 include a plurality of high bandwidth memories (HBM) 63a, 63b, 63c, 63d, 63e, and 63f. In this example, the interposer 61 may be the silicon carbide wafer described above.

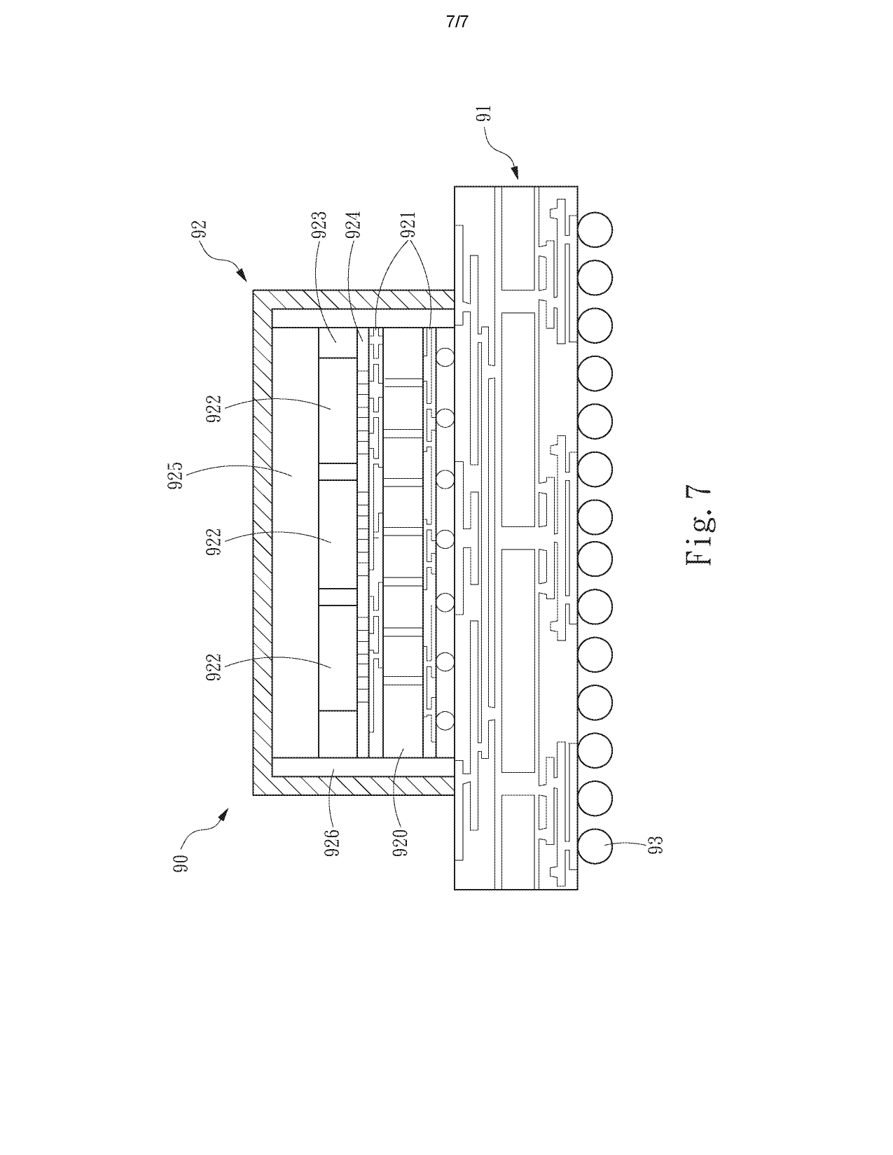

FIG. 7 illustrates another chip module 90 according to one embodiment of the present invention. The chip module 90 is a CoWoS (Chip on Wafer on Substrate with silicon interposer) packaging structure. The chip module 90 includes a substrate 91 and a chip package 92. The chip package 92 is disposed on the substrate 91. The chip package 92 includes an interposer 920, one or more redistribution layers (RDL) 921, one or more chips 922, one or more liquid molding compound (LMC) layers 923, one or more underfill layers 924, a thermal interface material 925, and a lid 926. The substrate 91 is disposed on a circuit board or another substrate through a solder ball array 93. In this example, the interposer 920 may be the silicon carbide wafer described above. The lid 926 may also be the silicon carbide wafer described above.

In some examples, the heat spreading layer serves as an interposer configured to redistribute solder balls of a ball grid array (BGA). The heat spreading layer is disposed between a chip and a substrate, and provides both electrical insulation and lateral heat spreading, thereby reducing thermal concentration around solder joints and improving solder joint reliability.

In some examples, the heat spreading layer is disposed within a three-dimensional (3D) stacked package. For example, the heat spreading layer may be positioned between stacked high bandwidth memory (HBM) dies, or between an HBM stack and a logic die, to dissipate heat generated by the stacked dies and to reduce vertical thermal resistance in the 3D package.

In some examples, the heat spreading layer is used as a heat sink or heat spreader for a power semiconductor chip or a radio-frequency (RF) chip. The heat spreading layer is disposed on a heat generating surface of the power chip or RF chip, and provides high thermal conductivity and electrical insulation, thereby improving heat dissipation performance and device reliability.

In some examples, the heat spreading layer is provided with a metal film formed on at least one surface thereof. The metal film may include, for example, silver, copper, gold, or alloys thereof. In such embodiments, a chip is bonded to the heat spreading layer through the metal film by silver sintering, silver soldering, or another metal bonding process, thereby forming a thermally efficient and mechanically robust attachment between the chip and the heat spreading layer.

What is claimed is:

1. A heat spreading layer, comprising an at least partially transparent silicon carbide wafer or a slice thereof, used as an insulating layer of a chip, wherein the silicon carbide wafer or the slice thereof is obtained by slicing from a grown silicon carbide boule or ingot, and has a thermal conductivity higher than that of copper.

2. The heat spreading layer of claim 1, wherein the silicon carbide wafer or the slice thereof is single-crystal SiC, quasi-single-crystal SiC, large-grain SiC, few-grain SiC wafers or low-angle grain boundary SiC.

3. The heat spreading layer of claim 1, wherein the at least partially transparent silicon carbide wafer or the slice thereof has a bulk crystal structure with high lattice integrity, thereby exhibiting the thermal conductivity higher than 400 W/m·K.

4. The heat spreading layer of claim 1, wherein the insulating layer is an interposer or a direct bonded copper ceramic substrate.

5. The heat spreading layer of claim 1, wherein the silicon carbide wafer or the slice thereof is disposed on a thinned silicon wafer.

6. The heat spreading layer of claim 4, wherein the silicon carbide wafer or the slice thereof is attached to the thinned silicon wafer by soft solder or by a thermal interface material.

7. The heat spreading layer of claim 1, wherein the heat spreading layer forms part of a system-on-a-chip.

8. The heat spreading layer of claim 1, wherein the heat spreading layer has a square or rectangular shape.

9. The heat spreading layer of claim 1, wherein the silicon carbide wafer or the slice thereof has a thickness less than 1 mm.

10. A heat spreading layer, comprising:
a first wafer, being an at least partially transparent silicon carbide wafer or a slice thereof, used as an insulating layer, wherein the silicon carbide wafer or the slice thereof is obtained by slicing from a grown silicon carbide boule or ingot; and
a second wafer, being a gallium nitride wafer, a gallium oxide wafer, or a slice thereof;
wherein the first wafer and the second wafer are bonded together by wafer bonding.

11. The heat spreading layer of claim 10, wherein the silicon carbide wafer or the slice thereof is single-crystal SiC, quasi-single-crystal SiC, large-grain SiC, few-grain SiC wafers or low-angle grain boundary SiC.

12. The heat spreading layer of claim 10, wherein the at least partially transparent silicon carbide wafer or the slice thereof has a bulk crystal structure with high lattice integrity, thereby exhibiting a thermal conductivity higher than 400 W/m·K.

13. The heat spreading layer of claim 10, wherein the insulating layer is an interposer or a direct bonded copper ceramic substrate.

14. The heat spreading layer of claim 10, wherein the silicon carbide wafer or the slice thereof is disposed on a thinned silicon wafer.

15. The heat spreading layer of claim 13, wherein the silicon carbide wafer or the slice thereof is attached to the thinned silicon wafer by soft solder or by a thermal interface material.

16. The heat spreading layer of claim 10, wherein the heat spreading layer forms part of a system-on-a-chip.

17. The heat spreading layer of claim 10, wherein the heat spreading layer has a square or rectangular shape.

18. The heat spreading layer of claim 10, wherein the silicon carbide wafer or the slice thereof has a thickness less than 1 mm.

19. A system-on-a-chip, comprising:
a thinned silicon wafer; and
a heat spreading layer formed on the thinned silicon wafer,
wherein the heat spreading layer is a transparent or partially transparent silicon carbide wafer or a slice thereof, and wherein the silicon carbide wafer or the slice thereof is obtained by slicing from a grown silicon carbide boule or ingot.

20. The system-on-a-chip of claim 19, wherein the silicon carbide wafer or the slice thereof is single-crystal SiC, quasi-single-crystal SiC, large-grain SiC, few-grain SiC wafers or low-angle grain boundary SiC.
